(19) United States
(12) Patent Application Publication
(10) Pub. No.: US 2020/0211910 A1
(43) Pub. Date: Jul. 2, 2020

(54) MULTILAYER MOS DEVICE AND METHOD FOR MANUFACTURING THE SAME

(71) Applicant: Institute of Microelectronics, Chinese Academy of Sciences, Beijing (CN)

(72) Inventors: Huaxiang YIN, Beijing (CN); Qingzhu ZHANG, Beijing (CN); Xiang LIN, Beijing (CN)

(73) Assignee: Institute of Microelectronics, Chinese Academy of Sciences

(21) Appl. No.: 16/722,406

(22) Filed: Dec. 20, 2019

(30) Foreign Application Priority Data
Dec. 29, 2018 (CN) 201811643642.8

(51) Int. Cl. H01L 21/84; H01L 27/12; H01L 23/522

(52) U.S. Cl. CPC H01L 21/84; H01L 21/283; H01L 23/5226; H01L 27/1207

(57) ABSTRACT

A multilayer MOS device and a method for manufacturing the same. The manufacturing method includes: providing a MOS device including n layers, where n is a natural number greater than zero; forming a semiconductor layer on the MOS device including n layers; forming a gate oxide layer and a dummy gate on the semiconductor layer sequentially, where at least a part of the gate oxide layer is located between the dummy gate and the semiconductor layer; forming a metal silicide layer in the semiconductor layer at two sides of the dummy gate, to obtain a MOS device of an (n+1)-th layer, where the metal silicide layer serves as a metallized source-drain region or the metal silicide layer is doped to form a metalized source-drain region; and connecting a MOS device of an n-th layer of the n layers with the MOS device of the (n+1)-th layer via metallic interconnection.

The present disclosure claims priority to Chinese Patent Application No. 201811643642.8, titled “MULTILAYER MOS DEVICE AND METHOD FOR MANUFACTURING THE SAME,” filed on Dec. 29, 2018 with the China National Intellectual Property Administration, the content of which is incorporated herein by reference.

### FIELD

The present disclosure relates to the technology field of semiconductor, and particularly, to a multilayer MOS (metal-oxide-semiconductor) device and a method for manufacturing the multilayer MOS device.

### BACKGROUND

With continuous development in CMOS (complementary metal-oxide-semicondutor) integrated circuits, MOS devices evolve from 2D (two-dimensional) planar structures to 3D (three-dimensional) FinFETs (fin field-effect transistors), and then to 3D Lateral GAA NW FETs (gate-all-around nanowire field-effect transistors) and 3D Vertical GAA NW FETs. Vertical single-chip 3D integration (M3D) structures are expected in the future.

Accordingly, microsystem integration that is based on the CMOS integrated circuit develops from 3D packaging, system-in-package (SiP), multi-chip 3D system integration (3D-SoC, three-dimensional silicon-on-chip) to single-chip 3D integration (3D-IC, three-dimensional integrated circuit). Thereby, microsystem volume, circuit latency and power consumption keeps being reduced, and system performances are greatly improved.

A multilayer MOS device may be formed through a process of the aforementioned single-chip three-dimensional integration. In a first layer, a MOS device with higher performance may be fabricated as long as a conventional manufacturing process is applied. For an upper layer, many steps in manufacturing a MOS device are carried out under a high temperature. For example, in forming a source region and a drain region, high temperature treatment (temperature is about 1050° C.) is necessary after ion implantation to activate implanted ions, so that the ions can diffuse in a certain range. High temperature in such steps would influence a MOS device in a lower layer that has been fabricated. In order to avoid the influence from the high temperature, the MOS device in the upper layer should be manufactured under a low temperature. Nevertheless, low temperature would influence device performances, resulting in a multilayer MOS device with poor performances.

### SUMMARY

In view of the above, a multilayer MOS device and a method for manufacturing the multilayer MOS device are provided according to an embodiment of the present disclosure, so as to address an issue of poor performances of a multilayer MOS device in conventional technology.

In one aspect, a method for manufacturing a multilayer MOS device is provided. The method includes: step S1, providing a MOS device including n layers, forming a semiconductor layer on the MOS device including n layers, and forming a gate oxide layer and a dummy gate on the semiconductor layer in the sequence listed, where n is a natural number greater than zero, and at least a part of the gate oxide layer is located between the dummy gate and the semiconductor layer; step S2, forming a metal silicide layer in the semiconductor layer at two sides of the dummy gate, to obtain a MOS device of an (n+1)-th layer, where the metal silicide layer serves as a metallized source-drain region or the metal silicide layer is doped to form a metalized source-drain region; and step S3, connecting a MOS device of an n-th layer of the n layers with the MOS device of the (n+1)-th layer via metallic interconnection.

In one embodiment, in the step S1, the semiconductor layer is formed under a temperature lower than 550° C. In one embodiment, the semiconductor layer is formed on a MOS device of a topmost layer of then layers through deposition or bonding.

In one embodiment, the semiconductor layer is a single layer or a stacked multilayer structure, which is formed by at least one of monocrystalline silicon, monocrystalline germanium, monocrystalline germanium silicon, polycrystalline silicon, polycrystalline germanium, or polycrystalline germanium silicon.

In one embodiment, after forming the dummy gate, the method further includes: forming a source-drain extension region in the semiconductor layer at the two sides of the dummy gate; and forming sidewalls at the two sides of the dummy gate, where each of the sidewalls covers at least a part of the source-drain extension region.

In one embodiment, in the step S2, the metal silicide layer is formed under a temperature lower than 600° C.

In one embodiment, the step S2 includes: step S21, depositing a metal material on the semiconductor layer at the two sides of the dummy gate; and step S22, performing heat treatment on the metal material to make the metal material react with a part of the semiconductor layer at the two sides of the dummy gate, and removing an unreacted part of the metal material to obtain the metal silicide layer, where the metal silicide layer serves as the metalized source-drain region.

In one embodiment, the step S2 includes: step S21, depositing a metal material on the semiconductor layer at the sides of the dummy gate; step S22, performing heat treatment process on the metal material to make the metal material react with a part of the semiconductor layer at the two sides of the dummy gate, and removing an unreacted part of the metal material to obtain the metal silicide layer; and step 23, doping the metal silicide layer through ion implantation to obtain the metalized source-drain region.

In one embodiment, the semiconductor layer includes a first semiconductor region, a second semiconductor region, and a third semiconductor region that are sequentially connected. The dummy gate is located in the second semiconductor region. The first semiconductor region and the third semiconductor region are located at two sides of the second semiconductor region. In the step S21, the metal material is deposited on the first semiconductor region and the third semiconductor region. In the step S22, the heat treatment performed on the metal material makes a part of the semiconductor layer in the first semiconductor region and the third semiconductor region react with the metal material, and the unreacted part of the metal material is removed to obtain a partially metalized source-drain region. Or, the heat treatment performed on the metal material makes all the semiconductor layer in the first semiconductor region and the third semiconductor region react with the metal material, and the unreacted part of the metal material is removed to obtain a completely metalized source-drain region.

In one embodiment, the metal silicide layer is made of MSi or MSi2, where M represents a metal element. In one embodiment, the metal element is one or more of Ni, Ti, Co, Pt, or Al.

In one embodiment, after the step S2, the method further includes: removing the dummy gate, and forming a gate stack structure on the gate oxide layer, to obtain the MOS device of the (n+1)-th layer, where the metalized source-drain region are located at two sides of the gate stack structure.

In one embodiment, after the step S3, the method further includes: repeating the steps S1 to S3, to obtain the multilayer MOS device.

In one embodiment, at least one layer in the multilayer MOS device is a layer of a CMOS device.

In another aspect, a multilayer MOS device is provided according to an embodiment of the present disclosure. The multilayer MOS device includes a MOS device of a first layer and a MOS device including n layers that are sequentially stacked on the MOS device of the first layer, where N is a natural number greater than zero. The multilayer MOS device further includes a metallic interconnection structure connecting MOS devices in all adjacent layers among the first layer and the N layers. A MOS device of an M-th layer in the N layers includes: a semiconductor layer located on a MOS device of an (M−1)-th layer, where M is a natural number greater than 1 and less than or equal to N; a gate structure, including a gate and a gate oxide layer, where at least a part of the gate oxide layer is located between the gate and the semiconductor layer; and a metalized source-drain region, located in the semiconductor layer at two sides of the gate structure, where the metalized source-drain region is a metal silicide layer or a doped metal silicide layer.

In one embodiment, the metalized source-drain region is a partially metalized source-drain region or a completely metalized source-drain region.

The method for manufacturing the multilayer MOS device is provided in technical solutions according to embodiments of the present disclosure. The metal silicide layer is firstly formed in the semiconductor layer on the two sides of the dummy gate, and then the metal silicide layer is doped to form the source-drain region, so as to acquire a metalized source-drain (MSD) region. Therefore, a source-drain parasitic resistance is reduced, and a high-performance device can be fabricated under a low temperature. Further, a requirement on activation temperature for dopant is greatly reduced in a conventional process, and a harmful influence of an increased parasitic and contact resistance due to insufficient activation is reduced for the device. Deficiencies in conventional single-chip three-dimensional integration are avoided, and a performance of the multilayer MOS device is improved.

### BRIEF DESCRIPTION OF THE DRAWINGS

For clearer illustration of the technical solutions according to embodiments of the present disclosure or conventional techniques, hereinafter are briefly described the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIGS. 1 to 8 are schematic structural diagrams of cross-sectional views of a substrate in a process of a method for manufacturing a multilayer MOS device according to an embodiment of the present disclosure;

FIG. 9 is a schematic structural diagram of a multilayer MOS device according to an embodiment of the present disclosure.

Reference numerals:

| | |
|---|---|
| 10: first layer MOS device; | 110: first source-drain region; |
| 120: first gate; | 130: first interlayer dielectric layer; |
| 210: semiconductor layer; | 211: patterned semiconductor layer; |
| 220: dummy gate; | 230: source-drain extension region; |
| 240: sidewall; | 250: metalized source-drain region; |
| 260: gate stack structure; | 270: interlayer dielectric layer; |
| 30: metallic interconnection | 301: metal wiring. |
| structure; | |

### DETAILED DESCRIPTION

It should be noted that embodiments and features in the embodiments of the present disclosure may be combined with each other in case of there being no conflict. Hereinafter reference is made to the drawings to describe the present disclosure in detail in conjunction with embodiments.

Hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. For example, a process, a method, an article or a device including a series of elements include is not limited to the disclosed elements, and may include other elements that are not clearly enumerated, or further include inherent elements of the process, the method, the article or the device.

As described in the background, in manufacture of a multilayer MOS device, a high temperature would influence a MOS device that has been fabricated in a lower layer. Thereby, a MOS device of an upper layer should be fabricated under a low temperature in order to avoid such influence. Nevertheless, a low temperature would influence a performance of the device, thereby failing to obtain a multilayer MOS device with a good performance.

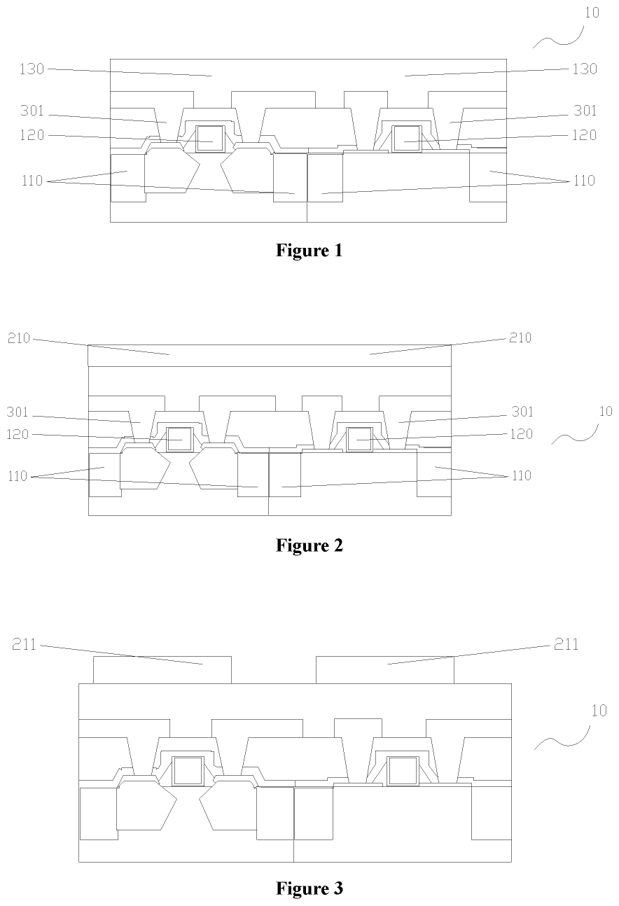

A method manufacturing for a multilayer MOS device is provided according to an embodiment of the present disclosure. As shown in FIGS. 1 to 8, the method includes steps S1 to S3.

In step S1, a MOS device including n layers is provided, where n is a natural number greater than zero. Then, a semiconductor layer 210 is formed on the MOS device including n layers, and a gate oxide layer and a dummy gate 220 are formed on the semiconductor layer 210 in the sequence listed. At least a part of the gate oxide layer is located between the dummy gate 220 and the semiconductor layer 210.

In step S2, a metal silicide layer in the semiconductor layer 210 at two sides of the dummy gate 220 are formed to obtain a MOS device of an (n+1)-th layer. The metal silicide layer serves as a metallized source-drain region 250, or the metal silicide layer is doped to form a metalized source-drain region 250.

In step S3, a MOS device of an n-th layer of the n layers is connected with the MOS device of the (n+1)-th layer via metallic interconnection.

In the aforementioned method, the metal silicide layer is firstly formed in the semiconductor layer on the two sides of the dummy gate, and then the metal silicide layer is doped to form the source-drain region, so as to acquire a metalized source-drain (MSD) region. Therefore, a source-drain parasitic resistance is reduced, and a high-performance device can be fabricated under low temperature. Further, a requirement on activation temperature for dopant is greatly reduced in a conventional process, and a harmful influence of an increased parasitic and contact resistance due to insufficient activation is reduced for the device. Deficiencies in conventional single-chip three-dimensional integration are avoided, and a performance of the multilayer MOS device is improved.

Hereinafter embodiments of the manufacturing method for the multilayer MOS device are described in more details. The embodiments may be implemented in various different manners and should not be construed as limitations to the present disclosure. It is understood that the embodiments are provided for disclosing the present disclosure more completely, and conveying concepts of the embodiment to those skilled in the art more thoroughly.

Firstly, the step S1 is performed with reference to FIGS. 1 to 4. A least one MOS device including n layers is provided, where n is a natural number greater than zero. Then, a semiconductor layer 210 is formed on the MOS device including n layers, and a gate oxide layer and a dummy gate 220 are formed on the semiconductor layer 210 in the sequence listed. At least a part of the gate oxide layer is located between the dummy gate 220 and the semiconductor layer 210.

The MOS device including n layers may be a MOS device of a single layer, or a MOS device with multiple layers. The MOS device of the single layer, in case of n=1, and a MOS device 10 of a first layer, in case of n>1, may be manufactured through a conventional process. The conventional process may include following steps. A first gate 120 is formed on a substrate. A first source-drain region 110 is formed through ion implantation in the substrate at two sides of the first gate 120. A first interlayer dielectric layer 130 is formed through deposition, covering the first gate 120 and the first source-drain region 110. Metal wiring 301 of the first layer is formed in the first interlayer dielectric layer 130, and the metal wiring 301 is connected to the first gate 120 and the first source-drain region, respectively. Reference is made to FIG. 1. A person skilled in the art may select reasonable process conditions for the above steps according to conventional technology. Further, fabrication of the above MOS device is not limited to the aforementioned steps, and those skilled in the art may make reasonable configurations according to actual requirements.

In one embodiment, the semiconductor layer 250 is formed under a temperature lower than 550° C. in the step S1, in order to avoid an influence of high temperature on the MOS device of a lower layer. The semiconductor layer 210 may be formed on a MOS device of a topmost layer of the n layers through deposition or bonding. A semiconductor material applied under low temperature may be a single layer or a stacked multilayer structure, which is formed by at least one of monocrystalline silicon, monocrystalline germanium, monocrystalline germanium silicon, polycrystalline silicon, polycrystalline germanium, or polycrystalline germanium silicon.

After forming the dummy gate 220, step S1 may further include a following step. The semiconductor layer 210 is patterned, so as to obtain a patterned semiconductor layer 211 corresponding to an active region of a pre-formed device. Reference is made to FIG. 3.

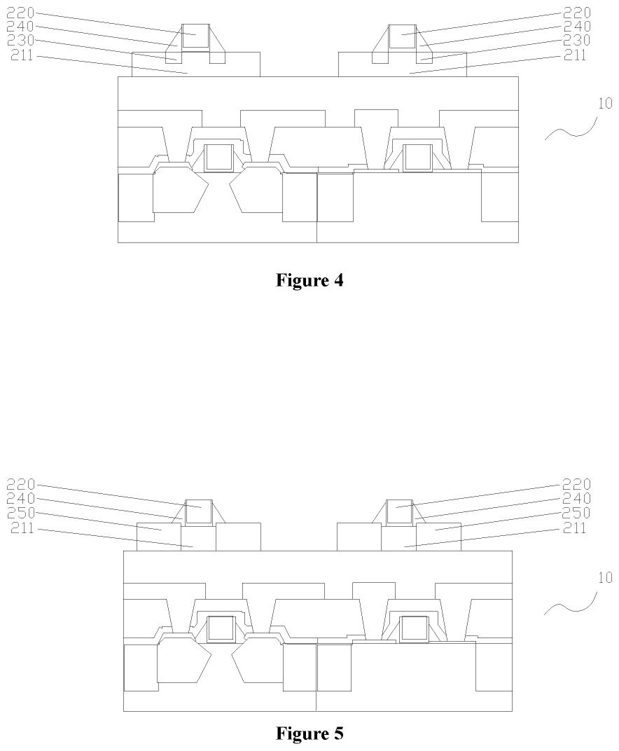

After forming the dummy gate 220, step S1 may further include following steps. A dummy source-drain extension region 230 in the semiconductor layer 210 is formed at the two sides of the dummy gate 220. Sidewalls 240 are formed at the two sides of the dummy gate 220. Each sidewall 240 covers at least a part of the dummy source-drain extension region 230. Reference is made to FIG. 4.

The step S2 is performed after the step S1. A metal silicide layer in the semiconductor layer 210 are formed in a region corresponding to two sides of the dummy gate 220, so as to obtain a MOS device of an (n+1)-th layer. The metal silicide layer serves as the metallized source-drain region 250, or the metal silicide layer is doped to form the metalized source-drain region 250. Reference is made to FIG. 5. The metal silicide layer is introduced to achieve an ohmic contact between a contact hole and a source-drain region. Thereby, a contact resistance is reduced and a driving current is increased, improving a performance of the device.

In one embodiment, the metal silicide layer is formed under a temperature lower than 600° C. in the step S2, in order to avoid an influence of high temperature on a MOS device of a lower layer.

In one embodiment, forming the metalized source-drain region 250 under low temperature includes steps S21 and S22. In step S21, a metal material is deposited on the semiconductor layer 210 at the two sides of the dummy gate 220. In step S22, heat treatment is performed on the metal material to make the metal material react with a part of the semiconductor layer 210 at the two sides of the dummy gate 220. An unreacted part of the metal material is removed to obtain the metal silicide layer. The metal silicide layer serves as the metalized source-drain region 250.

In one embodiment, forming the metalized source-drain region 250 under low temperature includes steps S21 to S23. In step S21, a metal material is deposited on the semiconductor layer 210 at the two sides of the dummy gate 220. In step S22, heat treatment is performed on the metal material under a temperature lower than 600° C. to make the metal material react with a part of the semiconductor layer 210 at the two sides of the dummy gate 220. An unreacted part of the metal material is removed to obtain the metal silicide layer. In step S23, the metal silicide layer is doped through ion implantation to obtain the metalized source-drain region 250.

In the above embodiments, the metal silicide layer may be MSi or MSi2, where M represents a metal element. In one embodiment, the metal element may be one or more of Ni, Ti, Co, Pt, or Al, in order to improve a performance of the device.

The semiconductor layer 210 may include a first semiconductor region, a second semiconductor region, and a third semiconductor region that are sequentially connected. The dummy gate 220 is located in the second semiconductor region. The first semiconductor region and the third semiconductor region are located at two sides of the second semiconductor region. In the step S21, the metal material is deposited on the first semiconductor region and the third semiconductor region. In step S22, the heat treatment performed on the metal material makes a part or whole of the semiconductor layer in the first semiconductor region react with the metal material, and a part or whole of the semiconductor layer in the first semiconductor region react with the metal material. The unreacted part of the metal material is removed to obtain a partially or completely metalized source-drain region.

In a case that the formed metalized source-drain region 250 is the partially metalized source-drain region, there is a part of the semiconductor layer that is not reacted under the metalized source-drain region 250. In a case that the formed metalized source-drain region 250 is a completely metalized source-drain region, the metalized source-drain region 250 may extend from an upper surface to a bottom surface of the semiconductor layer.

In the step S22, those skilled in the art can appropriately make reasonable configurations for steps and conditions of the aforementioned heat treatment, according to conventional technology. For example, the heat treatment performed on the metal material may include first thermal annealing and second thermal annealing. A intermediate phase with a high resistance is formed through the first thermal annealing on the semiconductor layer 210 that is covered with the metal material. Then, the high-resistance phase is converted into a desired low-resistance phase through the second thermal annealing. Generally, temperature of the second thermal annealing is higher than temperature of the first thermal annealing.

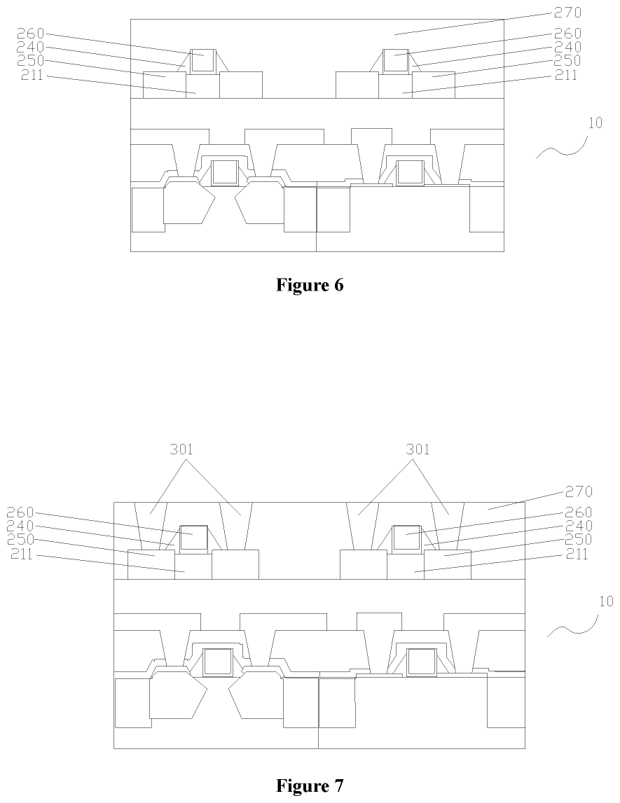

The dummy gate 220 formed in the step S1 may directly serve as a gate of the MOS device of the (n+1)-th layer. Alternatively, the dummy gate 220 is removed after the step S2, and then a gate stack structure 260 is formed on the gate oxide layer, to obtain the MOS device of the (n+1)-th layer on a MOS device of the n-th layer. Reference is made to FIG. 6. The metalized source-drain region 250 is located at two sides of the gate stack structure 260. The gate stack structure 260 is a gate of the MOS device of the (n+1)-th layer, and may include a high-k dielectric layer and a metal gate that are stacked. Each of the high-k dielectric layer and the metal gate may be a stacked structure. In practice, the gate structure may be separated from the sidewalls 240 by another high-k dielectric layer, as shown in FIGS. 6 to 9.

The dummy gate 220 may be selectively etched by using a TMHA solution. The metal gate may be made of TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni3Si, Pt, Ru, Ir, Mo, Ti, Al, Cr, Au, Cu, Ag, HfRu, RuOx, and the like. Those skilled in the art can make reasonable selections among these materials according to conventional technology.

After forming the gate as mentioned above, the method may further include following steps. An interlayer dielectric layer 270 is formed, covering the gate and the metalized source-drain region 250 of the MOS device of the (n+1)-th layer. Contact holes reaching the gate and the metalized source-drain region 250 are formed. The contact holes are filled with metal to form metal wiring 301 for the MOS device of the (n+1)-th layer. The metal wiring 301 is connected to the gate and the metalized source-drain region 250, respectively. Reference is made to in FIG. 7. The connection between the metal wiring 301 and the metalized source-drain region 250 is illustrated in FIG. 7, while the connection between the metal wiring 301 and the gate is omitted for concision.

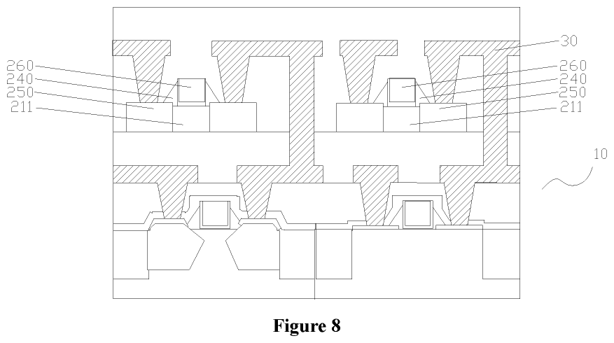

The step S3 is performed after the step S2. The MOS device of the n-th layer and the MOS device of the (n+1)-th layer are interconnected with each other. In one embodiment, the interlayer dielectric layer 270 covering the gate and the metalized source-drain region 250 of the MOS device of the (n+1)th layer may be formed. Contact holes are formed in the interlayer dielectric layer 270, and the contact holes reach the gate stack structure 260, the metalized source-drain region 250, and metal wiring 301 for the MOS device of a lower layer (that is, the MOS device of the n-th layer). The contact holes are filled with metal, to form metal wiring 301 for the MOS device of the (n+1)th layer. The metal wiring 301 for the MOS device of the n-th layer and the metal wiring 301 for the MOS device of the (n−1)-th layer are connected to form a metallic interconnection structure 30. Reference is made to FIG. 8. The connection between the metal wiring 301 and the metalized source-drain region 250 is illustrated in FIG. 8, while the connection between the metal wiring 301 and the gate is omitted for concision.

In one embodiment, the manufacturing method further include a following step after the step S3. The aforementioned steps S1 to S3 are repeated to obtain a multilayer MOS device. At least one layer in the multilayer MOS device may be a layer of a CMOS device, or each layer in the multiplayer MOS device is a layer of a CMOS device, thereby obtaining a multilayer CMOS device.

Taking a MOS device of three layers as an example, the method for manufacturing the MOS device may include the following steps.

First, a MOS device 10 of a first layer is manufactured through a conventional process. The MOS device 10 of the first layer includes a first gate 120, a first source-drain region 110, and metal wiring 301 that is connected with the first gate 120 and the source-drain regions 110, respectively.

Then, a semiconductor layer 210 is deposited or bonded on the MOS device 10 of the first layer. A dummy gate 220, a dummy source-drain extension region 230, and a sidewall 240 are formed on the semiconductor layer 210 in the sequence listed. A metal layer is deposited on the dummy gate 220, and heat treatment is performed on the metal layer, to form a metal silicide layer. The metal silicide layer is doped to obtain a metalized source-drain region 250. The dummy gate 220A is removed, and then a gate stack structure 260 is formed. Metal wring 301 connected with the gate stack structure 260 and the metalized source-drain region 250, respectively, is formed. Thereby, a MOS device of a second layer is fabricated.

Afterwards, another semiconductor layer 210 is deposited or bonded on the MOS device of the second layer. Another dummy gate 220, another dummy source-drain extension region 230, and another sidewall 240 are formed on the another second semiconductor layer 210 in the sequence listed. Another metal layer is deposited on the another dummy source-drain extension region 230, and heat treatment is performed on the another metal layer, to form another metal silicide layer. The another metal silicide layer is doped to obtain another metalized source-drain region 250. The another dummy gate 220A is removed, and then another gate stack structure 260 is formed. Metal wiring 301 connected to the another gate stack structure 260, the another metalized source-drain region 250, and the metal wiring for the MOS device of the second layer, respectively, is formed. Thereby, a MOS device of a third layer is fabricated. Metal wiring 301 in the MOS device of the three layers are connected with each other, forming a metallic interconnection structure 30 of the multilayer MOS device.

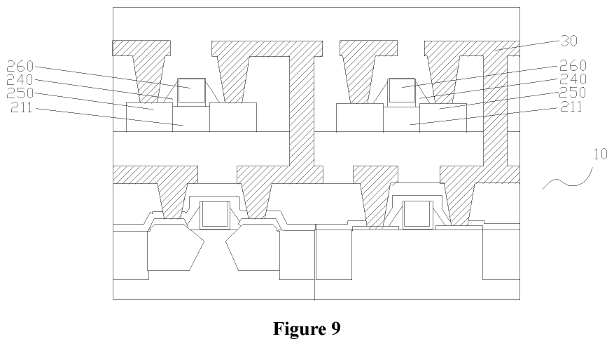

A multilayer MOS device is provided according to another embodiment of the present disclosure. Referring to FIG. 9, the multilayer MOS device includes a MOS device 10 of a first layer and a MOS device including n layers that are sequentially stacked on the MOS device 10 of the first layer, where N is a natural number greater than zero. The multilayer MOS device further includes a metallic interconnection structure 30 connecting MOS devices in all adjacent layers of the first layer and the N layers. A MOS device of an M-th layer in the N layers includes a semiconductor layer 210, a gate structure, and a metalized source-drain region 250. The semiconductor layer 210 is located on a MOS device of an (M−1)-th layer, where M is a natural number greater than 1 and less than or equal to N. The gate structure includes a gate and a gate oxide layer, where at least a part of the gate oxide layer is located between the gate and the semiconductor layer 210. The metalized source-drain region 250 is located in the semiconductor layer 210 at two sides of the gate structure, where the metalized source-drain region 250 is a metal silicide layer or a doped metal silicide layer.

Since at least one layer in the multilayer MOS device has a metalized source-drain (MSD) region, the source-drain parasitic resistance is reduced greatly. A high-performance device can be fabricated under a low temperature, thereby greatly reducing a requirement on activation temperature for dopant in conventional processes. A harmful influence of an increased parasitic and contact resistance due to insufficient activation is reduced for the device. Deficiencies of in conventional process of single-chip three-dimensional integration are avoided, and a performance of the multilayer MOS device is improved.

In one embodiment, the metalized source-drain region 250 may be a partially metalized source-drain region or a completely metalized source-drain region. In a case that the formed metalized source-drain region 250 is the partially metalized source-drain region, there is a part of the semiconductor layer that is not reacted under the metalized source-drain region 250. In a case that the formed metalized source-drain region 250 is a completely metalized source-drain region, the metalized source-drain region 250 may extend from an upper surface to a bottom surface of the semiconductor layer.

In one embodiment, the dummy gate 220 may directly serve as a gate of the MOS device. Alternatively, the dummy gate 220 is removed, and a gate stack structure 260 is formed on the gate oxide layer. Reference is made to FIG. 9. The metalized source-drain region 250 is located at two sides of the gate stack structure 260. The gate stack structure 260 is a gate of the MOS device of that layer, and may include a high-k dielectric layer and a metal gate that are stacked.

It can be seen from the above description that following technical effects are achieved according to the embodiments of the present disclosure.

In the aforementioned method, the metal silicide layer is firstly formed in the semiconductor layer on the two sides of the dummy gate, and then the metal silicide layer is doped to form the source-drain region, so as to acquire a metalized source-drain (MSD) region. Therefore, a source-drain parasitic resistance is reduced, and a high-performance device can be fabricated under low temperature. Further, a requirement on activation temperature for dopant is greatly reduced in a conventional process, and a harmful influence of an increased parasitic and contact resistance due to insufficient activation is reduced for the device. Deficiencies in conventional single-chip three-dimensional integration are avoided, and a performance of the multilayer MOS device is improved.

As described above, the above embodiments are only intended to describe the technical solutions of the present disclosure, and not to limit the present disclosure. Although the present disclosure is described in detail with reference to the above embodiments, those skilled in the art should understand that, modifications can be made to the technical solutions recorded in the above embodiments, or equivalent replacements can be made to some of the technical features thereof, and the modifications and the replacements will not make the corresponding technical solutions deviate from the spirit and the scope of the technical solutions of the embodiments of the present disclosure.

1. A method for manufacturing a multilayer MOS device, comprising:
providing a MOS device comprising n layers, wherein n is a natural number greater than zero;
forming a semiconductor layer on the MOS device comprising the n layers;
forming a gate oxide layer and a dummy gate on the semiconductor layer in the sequence listed, wherein at least a part of the gate oxide layer is located between the dummy gate and the semiconductor layer;
forming a metal silicide layer in the semiconductor layer at two sides of the dummy gate, to obtain a MOS device of an (n+1)-th layer, wherein the metal silicide layer serves as a metallized source-drain region or the metal silicide layer is doped to form a metalized source-drain region; and
connecting a MOS device of an n-th layer of the n layers with the MOS device of the (n+1)-th layer via metallic interconnection.

2. The method according to claim 1, wherein the semiconductor layer is formed under a temperature lower than 550° C., and the semiconductor layer is formed on a MOS device of a topmost layer of the n layers through deposition or bonding.

3. The method according to claim 1, wherein the semiconductor layer is a single layer or a stacked multilayer structure, which is formed by at least one of monocrystalline silicon, monocrystalline germanium, monocrystalline germanium silicon, polycrystalline silicon, polycrystalline germanium, or polycrystalline germanium silicon.

4. The method according to claim 2, wherein the semiconductor layer is a single layer or a stacked multilayer structure, which is formed by at least one of monocrystalline silicon, monocrystalline germanium, monocrystalline germanium silicon, polycrystalline silicon, polycrystalline germanium, or polycrystalline germanium silicon.

5. The method according to claim 1, wherein after forming the dummy gate, the method further comprises:
forming a source-drain extension region in the semiconductor layer at the two sides of the dummy gate; and
forming sidewalls at the two sides of the dummy gate, wherein each of the sidewalls covers at least a part of the source-drain extension region.

6. The method according to claim 1, wherein the metal silicide layer is formed under a temperature lower than 600° C.

7. The method according to claim 6, wherein forming the metal silicide layer in the semiconductor layer at the two sides of the dummy gate comprises:
depositing a metal material on the semiconductor layer at the two sides of the dummy gate; and
performing heat treatment on the metal material to make the metal material react with a part of the semiconductor layer at the two sides of the dummy gate; and
removing an unreacted part of the metal material to obtain the metal silicide layer, wherein the metal silicide layer serves as the metalized source-drain region.

8. The method according to claim 6, wherein forming the metal silicide layer in the semiconductor layer at the two sides of the dummy gate comprises:
depositing a metal material on the semiconductor layer at the two sides of the dummy gate; and
performing heat treatment on the metal material to make the metal material react with a part of the semiconductor layer at the two sides of the dummy gate;
removing an unreacted part of the metal material to obtain the metal silicide layer; and
doping the metal silicide layer through ion implantation to obtain the metalized source-drain region.

9. The method according to claim 7, wherein:
the semiconductor layer comprises a first semiconductor region, a second semiconductor region, and a third semiconductor region that are sequentially connected;
the dummy gate is located in the second semiconductor region;
the first semiconductor region and the third semiconductor region are located at two sides of the second semiconductor region; and
the metal material is deposited on the first semiconductor region and the third semiconductor region; and
wherein:
the heat treatment performed on the metal material makes a part of the semiconductor layer in the first semiconductor region and the third semiconductor region react with the metal material, and the unreacted part of the metal material is removed to obtain a partially metalized source-drain region; or
the heat treatment performed on the metal material makes all the semiconductor layer in the first semiconductor region and the third semiconductor region react with the metal material, and the unreacted part of the metal material is removed to obtain a completely metalized source-drain region.

10. The method according to claim 8, wherein:
the semiconductor layer comprises a first semiconductor region, a second semiconductor region, and a third semiconductor region that are sequentially connected;
the dummy gate is located in the second semiconductor region;
the first semiconductor region and the third semiconductor region are located at two sides of the second semiconductor region; and
the metal material is deposited on the first semiconductor region and the third semiconductor region; and
wherein:
the heat treatment performed on the metal material makes a part of the semiconductor layer in the first semiconductor region and the third semiconductor region react with the metal material, and the unreacted part of the metal material is removed to obtain a partially metalized source-drain region; or
the heat treatment performed on the metal material makes all the semiconductor layer in the first semiconductor region and the third semiconductor region react with the metal material, and the unreacted part of the metal material is removed to obtain a completely metalized source-drain region.

11. The method according to claim 7, wherein:
the metal silicide layer is made of MSi or MSi2, and M represents a metal element; and
the metal element is one or more of Ni, Ti, Co, Pt, or Al.

12. The method according to claim 8, wherein:
the metal silicide layer is made of MSi or MSi2, and M represents a metal element; and
the metal element is one or more of Ni, Ti, Co, Pt, or Al.

13. The method according to claim 1, wherein after forming the metal silicide layer in the semiconductor layer at the two sides of the dummy gate, the method further comprises:
removing the dummy gate; and
forming a gate stack structure on the gate oxide layer, to obtain the MOS device of the (n+1)-th layer, wherein the metalized source-drain region are located at two sides of the gate stack structure.

14. The method according to claim 1, wherein after connecting the MOS device of an n-th layer of the n layers with the MOS device of the (n+1)-th layer via the metallic interconnection, the method further comprises:
forming a MOS device of another layer on the (n+1)-th layer, through an identical process in forming the MOS device of the (n+1)th layer; and
connecting the MOS device of the another layer with the MOS device of the (n+1)-th layer via another metallic interconnection.

15. The manufacturing method according to claim 1, wherein at least one layer in the multilayer MOS device is a layer of a CMOS device.

16. A multilayer MOS device, comprising:
a MOS device of a first layer;
a MOS device comprising n layers that are sequentially stacked on the MOS device of the first layer, wherein N is a natural number greater than zero; and
a metallic interconnection structure connecting MOS devices in all adjacent layers among the first layer and the N layers;
wherein a MOS device of an M-th layer in the N layers comprises:
a semiconductor layer, located on a MOS device of an (M−1)-th layer, wherein M is a natural number greater than 1 and less than or equal to N;
a gate structure, comprising a gate and a gate oxide layer, wherein at least a part of the gate oxide layer is located between the gate and the semiconductor layer; and
a metalized source-drain region, located in the semiconductor layer at two sides of the gate structure, wherein the metalized source-drain region is a metal silicide layer or a doped metal silicide layer.

17. The multilayer MOS device according to claim 16, wherein the metalized source-drain region is a partially metalized source-drain region or a completely metalized source-drain region.
